(19) United States
(12) Patent Application Publication
(10) Pub. No.: US 2026/0136888 A1
(43) Pub. Date: May 14, 2026

(54) PRE-ASSEMBLY DEVICE FOR SEMICONDUCTOR DEVICES, AND SURFACE MOUNT DEVICE

(71) Applicant: TUDATONG (SUZHOU) CO., LTD., SUZHOU (CN)

(72) Inventors: Guixia Tian, SUZHOU (CN); Ben Du, SUZHOU (CN)

(73) Assignee: TUDATONG (SUZHOU) CO., LTD., SUZHOU, JS (CN)

(21) Appl. No.: 19/382,870

(22) Filed: Nov. 7, 2025

(30) Foreign Application Priority Data
Nov. 12, 2024 (CN) 202422755207.1

(51) Int. Cl. H01L 21/687; H01L 21/683

(52) U.S. Cl. CPC H10P 72/76; H10P 72/78

(57) ABSTRACT

Provided in the present disclosure is a pre-assembly device for semiconductor devices. The pre-assembly device comprises a clamping fixture and a surface mount mechanism. The clamping fixture includes at least one first member for limiting a position of at least one semiconductor device in at least a first direction, and a second member having a first predetermined area for arranging a cushion block. The surface mount mechanism is configured to move the cushion block to the first predetermined area. At least one side of the cushion block is used to limit the position of the at least one semiconductor device in at least a second direction that differs from the first direction and lies in the same plane as the first direction. According to the pre-assembly device in the present disclosure, the semiconductor devices can be accurately positioned and limited in position.

### TECHNICAL FIELD

The present disclosure relates to the field of semiconductor manufacturing, and in particular, to a pre-assembly device for semiconductor devices, and a surface mount device.

### BACKGROUND

The surface mount technology (SMT) is a technology and process widely used in the electronic assembly industry. It refers to a circuit connection technology that involves mounting leadless or short-leaded surface mount components on the surface of a printed circuit board (PCB) or other substrates, and then soldering and assembling them through methods such as reflow soldering.

With the rapid development of electronic technology, especially the continuous advancement of semiconductor device technology, conventional SMT equipment is facing new challenges, especially the difficulty in meeting the requirements for high packaging precision or high alignment accuracy of semiconductor devices. The methods described in this section are not necessarily those that have been previously envisioned or adopted. Unless otherwise indicated, none of the methods described in this section should be assumed to be the prior art merely because they are included in this section. Similarly, unless otherwise indicated, the problems mentioned in this section should not be considered as having been recognized in any prior art.

### SUMMARY

The present disclosure is intended to solve at least one of the technical problems existing in the background. In view of this, an objective of the present disclosure is to provide a pre-assembly device for semiconductor devices, which alleviates or improves the problems in the related art by pre-assembling the semiconductor devices.

According to a first aspect of an embodiment of the present disclosure, a pre-assembly device for semiconductor devices is provided. The pre-assembly device includes a clamping fixture and a surface mount mechanism. The clamping fixture includes at least one first member for limiting a position of at least one semiconductor device in at least a first direction, and a second member having a first predetermined area for arranging a cushion block. The surface mount mechanism is configured to move the cushion block to the first predetermined area. At least one side of the cushion block is used to limit the position of the at least one semiconductor device in at least a second direction that differs from the first direction and lies in the same plane as the first direction.

According to a second aspect of an embodiment of the present disclosure, a surface mount device is provided, including the pre-assembly device for semiconductor devices according to the first aspect described above.

By arranging the cushion block and the first and second members of the clamping fixture, the positions of the semiconductor devices can be limited in at least two directions. The pre-assembly device for semiconductor devices according to an embodiment of the present disclosure can improve the positional accuracy between the semiconductor devices with low cost and a simple process, thereby enhancing the mounting accuracy in the SMT process and enabling adaptation to high-density component integration.

### BRIEF DESCRIPTION OF THE DRAWINGS

The drawings exemplarily illustrate embodiments and constitute part of the specification, and together with the textual description of the specification, serve to illustrate exemplary implementations of the embodiments. The embodiments shown are for illustrative purposes only and do not limit the scope of claims. In all the drawings, the same reference numerals refer to the same elements or similar but not necessarily identical elements.

FIG. 1 shows a schematic diagram of a clamping fixture in a pre-assembly device for semiconductor devices according to an embodiment of the present disclosure;

FIG. 2 shows a schematic diagram of a clamping fixture in a pre-assembly device for semiconductor devices according to an embodiment of the present disclosure; and

FIG. 3 shows a schematic diagram in which a semiconductor device assembly is mounted on a PCB according to an embodiment of the present disclosure.

### Description of Reference Numerals

100: clamping fixture; 110, 110a, 110b: first member; 120: second member;
200: cushion block; 300, 300a, 300b: semiconductor device;
X: first direction; Y: second direction;
10: semiconductor device assembly; 400: vacuum cavity; and 500: PCB.

### DETAILED DESCRIPTION OF THE EMBODIMENTS

Further detailed description of the present disclosure will be provided below in conjunction with the drawings and embodiments. It can be understood that the specific embodiments described herein are merely to illustrate the related invention, and are not intended to limit the invention. Additionally, it should be noted that for ease of description, only parts related to the related invention are shown in the drawings.

It should be noted that the embodiments of the present disclosure and the features in the embodiments may be combined with each other unless without conflict. Unless otherwise explicitly stated in the context, if the number of elements is not specifically limited, the element can be one or plural. In addition, the numbers of steps or functional modules used in the present disclosure are only used to identify each step or functional module, and are not used to limit the execution order of each step or the connection relationship between each functional module.

In the present disclosure, unless otherwise specified, the use of the terms “first”, “second”, etc. to describe various elements is not intended to define the positional relationship, temporal relationship, or importance relationship of these elements, and such terms are simply used to distinguish one element from another element. In some examples, the first element and the second element may refer to the same instance of the element, while in some cases, they may also refer to different instances based on contextual descriptions.

In the present disclosure, the terms used in the description of various described examples are for the purpose of describing specific examples only, and are not intended to be limiting. Unless otherwise explicitly stated in the context, if the number of elements is not specifically limited, the element can be one or plural. In addition, the term “and/or” used in the present disclosure encompasses any one and all possible combinations of the listed items.

A basic SMT process includes screen printing, curing (surface mount), reflow soldering, inspection, and packaging. In the related art, an automatic surface mount machine is typically used to place devices to be mounted onto PCB pads printed with solder paste respectively. Subsequently, a PCB with mounted devices is passed through a reflow oven, where the solder paste melts and reflows at a high temperature, and cools to form solid solder joints that fix the devices to the PCB. However, the high-temperature reflow often causes device displacement, and the devices located at their respective predetermined positions before reflow may lead to mismatch between the devices due to differences in their respective offsets, which in turn affects the functionality of the devices.

For semiconductor devices with requirements for high packaging precision or high alignment accuracy, the impact of mismatch between the devices may be greater. For example, in the field of laser radars, an optoelectronic device with packaging precision at a micron (μm) level, such as a silicon photomultiplier (SiPM), is commonly used in a transceiver module to meet the requirements of high-precision coupling and matching between a receiver (Rx) and a transmitter (Tx). An alignment reference between these optoelectronic devices is a small aperture or photosensitive surface, so positional deviation caused by high-temperature reflow may result in more severe alignment mismatch for such devices.

In view of this, the present disclosure provides a pre-assembly device for semiconductor devices, where positions of the semiconductor devices can be limited in at least two directions by arranging a cushion block and first and second members of a clamping fixture. The pre-assembly device for semiconductor devices according to an embodiment of the present disclosure can improve the positional accuracy between the semiconductor devices with low cost and a simple process, thereby enhancing the mounting accuracy in the SMT process and enabling adaptation to high-density component integration.

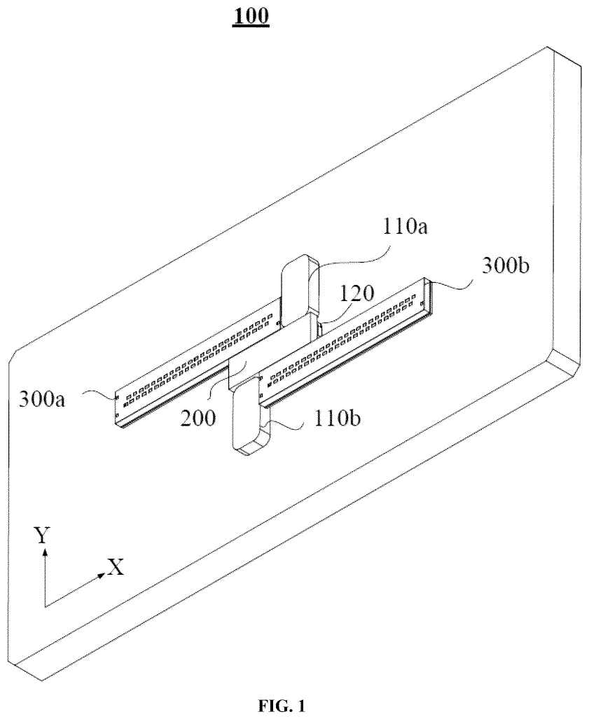

FIG. 1 shows a schematic diagram of a clamping fixture in a pre-assembly device for semiconductor devices according to an embodiment of the present disclosure.

The pre-assembly device for semiconductor devices in the present disclosure includes a clamping fixture 100 and a surface mount mechanism (not shown in the figure).

The clamping fixture 100 includes at least one first member 110 and a second member 120. The at least one first member 110 is configured to limit a position of at least one semiconductor device 300 in at least a first direction X, and the second member 120 has a first predetermined area for arranging a cushion block 200. The surface mount mechanism is configured to move the cushion block 200 to the first predetermined area. At least one side of the cushion block 200 is used to limit the position of the at least one semiconductor device in at least a second direction Y. The second direction Y differs from the first direction X and lies in the same plane as the first direction X.

In this embodiment of the present disclosure, the clamping fixture is provided for accurately positioning the semiconductor device. FIG. 1 shows an example in which a clamping fixture positions a 2×1 semiconductor device array according to the present disclosure.

In the example shown in FIG. 1, the clamping fixture 100 includes two first members 110a and 110b configured to respectively limit positions of semiconductor devices 300a and 300b in the direction X. In some embodiments, a respective side of each of the semiconductor devices 300a and 300b extending along the direction Y (e.g., a first side) can abut against a corresponding side of each of the first members 110a and 110b, thereby limiting relative positions of the semiconductor devices 300a and 300b in the direction X. The second member 120 is disposed between the first members 110a and 110b along the second direction Y, and has a first predetermined area for arranging the cushion block 200. The first predetermined area can be predetermined based on a layout of the semiconductor device array.

In the example shown in FIG. 1, the second member 120 is configured to include a protrusion, and the cushion block 200 is located above the protrusion. It should be understood that other configurations are also possible, for example, the second member 120 can also include a groove for limiting the first predetermined area. After the cushion block 200 is moved to the first predetermined area by the surface mount mechanism, the positions of the semiconductor devices 300a and 300b can be limited in the direction Y. In the example shown in FIG. 1, two opposite sides of the cushion block 200 respectively abut against corresponding sides of the semiconductor devices 300a and 300b extending in the direction X (e.g., second sides), thereby limiting relative positions of the semiconductor devices 300a and 300b in the direction Y.

It should be understood that the number, positions, or arrangement of the members in the present disclosure can be adjusted depending on design requirements of the semiconductor device array. For example, when a 2×2 semiconductor device array is positioned, the number of first members in the clamping fixture may be four, and the second member 120 in FIG. 1 may be a protrusion with an extended length in the direction X. Accordingly, the cushion block 200 also has an extended length in the direction X, such that another set of semiconductor devices can abut against corresponding sides of the cushion block along the direction X.

By arranging the cushion block and the first and second members of the clamping fixture, the positions of the semiconductor devices can be limited in at least two directions, thereby improving the positional accuracy between the semiconductor devices.

In some embodiments, the surface mount mechanism may include a suction head for picking up and placing the cushion block or the semiconductor device. In some embodiments, the surface mount mechanism further includes a robotic arm connected to the suction head and configured to provide movement of the suction head in different directions (e.g., a direction X and a direction Y shown in FIG. 1, and a direction Z perpendicular to a plane defined by the direction X and the direction Y). In some embodiments, the surface mount mechanism further includes a tray, a belt, and a feeder which are configured to accommodate and convey the cushion block or the semiconductor device. It should be understood that the descriptions of the tray, the belt, and the feeder are for illustrative purposes only and are not essential to the objective of the present disclosure.

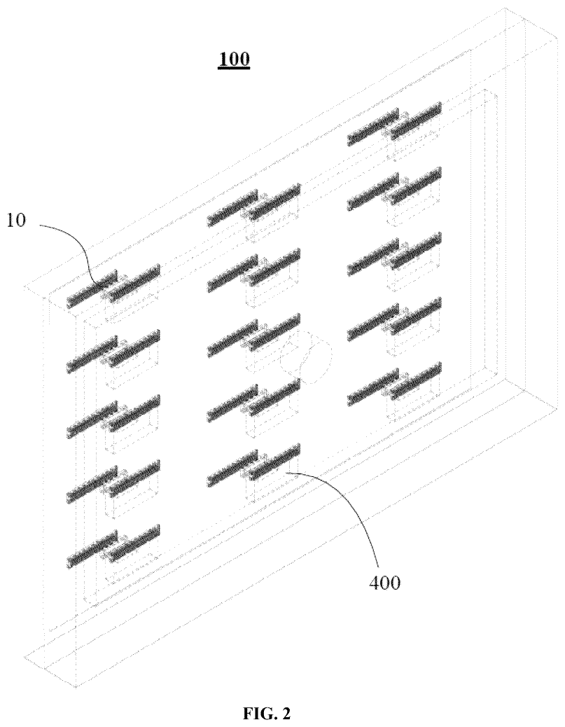

In some embodiments, the pre-assembly device further includes an image collector (not shown in the figure) and a controller (not shown in the figure). The image collector may be, for example, a CCD camera or an automatic optical inspection (AOI) device configured to acquire images of the cushion block 200, the first predetermined area, and the semiconductor device 300. The controller is communicatively connected to the image collector and the surface mount mechanism, and is configured to analyze and identify shapes, sizes, or positions of the cushion block 200, the first predetermined area, and the semiconductor device 300 acquired by the image collector, and to control, based on the above information, the cushion block 200 and the semiconductor device 300 to move. Examples of the controller include, but are not limited to, industrial control computers, such as an industrial personal computer (IPC), a programmable logic controller (PLC), a distributed control system (DCS), a fieldbus control system (FCS), or a computer numerical control (CNC) system. In some embodiments, the clamping fixture 100 may include a cushion block fixing apparatus (not shown in the figure) configured to fix the cushion block 200 in the first predetermined area. Referring to FIG. 1 and FIG. 2, the second member 120 is provided with a hole in the first predetermined area, and the cushion block fixing apparatus may include a vacuum machine (not shown in the figure) in fluid communication with the hole. The clamping fixture 100 includes a vacuum cavity 400, where the vacuum cavity 400 is in fluid communication with the hole and the vacuum machine. The controller first controls the suction head of the surface mount mechanism to pick up the cushion block 200 and move it to the first predetermined area. When the controller identifies, based on the image collected by the image collector, that the cushion block 200 is in place, the vacuum machine is controlled to start suction, and the suction head is controlled to release the cushion block 200, thereby accurately fixing the cushion block 200 to the clamping fixture 100.

In some embodiments, the pre-assembly device may further include an adhesive dispenser (not shown in the figure) for dispensing adhesive on at least one side of the cushion block 200 to fix at least one semiconductor device 300 to a corresponding side of the cushion block 200. Continuing to refer to FIG. 1 and FIG. 2, after the cushion block 200 is fixed to the clamping fixture 100, the controller controls the adhesive dispenser to dispense adhesive on two sides of the cushion block abutting against the semiconductor devices 300a and 300b. The controller then controls the suction head to respectively pick up the semiconductor devices 300a and 300b, and to respectively abut them against the corresponding sides of the first members 110a and 110b and the adhesive-dispensed corresponding sides of the cushion block 200, such that the semiconductor devices 300a and 300b are bonded and fixed to the cushion block 200, thereby forming a semiconductor device assembly 10.

The relative positional accuracy between the semiconductor devices in the semiconductor device assembly 10 can be significantly improved (for example, up to the μm level) by the limiting action of the clamping fixture 100 and the cushion block 200, thereby meeting the requirements for high packaging precision or high alignment accuracy of the semiconductor devices. For example, after an SiPM chip is formed into an assembly using the pre-assembly device for semiconductor devices in the present disclosure, the consistency of active coupling between an Rx end and a Tx end in a transceiver module of a laser radar is improved.

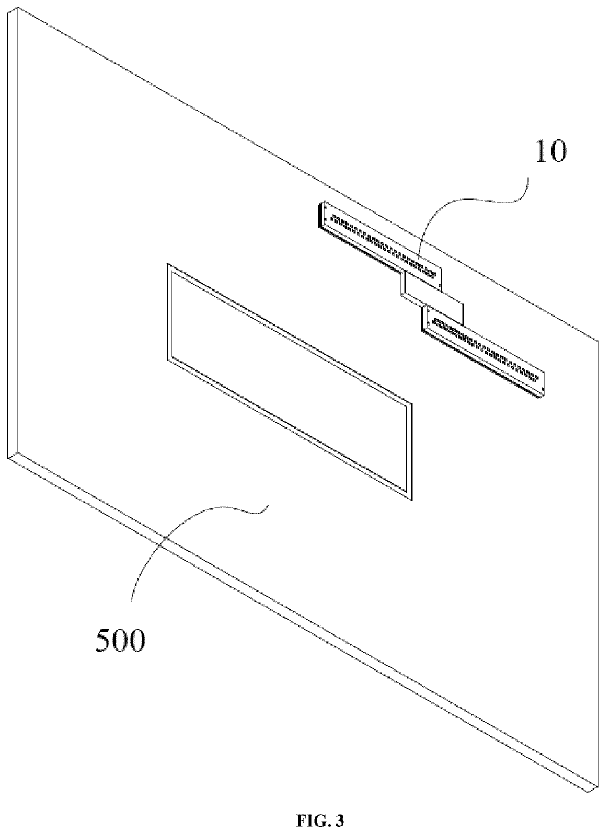

In some embodiments, the pre-assembly device further includes a curing machine (not shown in the figure) configured to bake and fix the cushion block 200 and the semiconductor devices 300a and 300b that are bonded in pairs. The curing machine can cure the adhesive between the cushion block 200 and the semiconductor devices 300a and 300b that are bonded by heating, thereby firmly fixing them. Reference is made to FIG. 3. FIG. 3 shows a schematic diagram in which a semiconductor device assembly 10 as a whole is mounted on a PCB 500. The cured semiconductor device assembly 10 can further reduce the possibility of different offsets between the devices, thereby improving the mismatch between the devices caused by high-temperature reflow in the SMT process.

In some embodiments, the surface mount mechanism further includes a film mounting machine (not shown in the figure) configured to mount a protective film on a surface of the semiconductor device. Mounting the protective film on the surface of the semiconductor device can reduce physical damage or contamination to the device during soldering, transportation, or storage. Furthermore, the protective film can also reduce damage to the semiconductor device caused by static electricity in an environment (especially in a dry environment).

In some embodiments, the cushion block 200 can be made of glass, and the clamping fixture 100 can be made of stainless steel. It should be understood that the materials for fabricating the cushion block and the clamping fixture can be selected according to actual requirements. For example, the cushion block can be made of a material compatible with the semiconductor device, and the clamping fixture can be made of a material with high stability.

In the present disclosure, a surface mount device is further provided, including the pre-assembly device for semiconductor devices according to any one of the embodiments described above.

Since the surface mount device includes the pre-assembly device for semiconductor devices according to any one of the embodiments described above, the surface mount device has the technical effects of the pre-assembly device described above, which will not be repeated herein.

The following describes some exemplary solutions of the present disclosure:

Solution 1. A pre-assembly device for semiconductor devices, including:
a clamping fixture, including at least one first member for limiting a position of at least one semiconductor device in at least a first direction, and a second member having a first predetermined area for arranging a cushion block; and
a surface mount mechanism, configured to move the cushion block to the first predetermined area;
where at least one side of the cushion block is used to limit the position of the at least one semiconductor device in at least a second direction that differs from the first direction and lies in the same plane as the first direction.

Solution 2. The pre-assembly device according to Solution 1, further including: an image collector, configured to collect images of the cushion block and the first predetermined area; and
a controller, communicatively connected to the image collector and the surface mount mechanism, and configured to determine a position of the cushion block relative to the first predetermined area based on the images of the cushion block and the first predetermined area, and control, based on the position, the surface mount mechanism to move the cushion block to the first predetermined area.

Solution 3. The pre-assembly device according to Solution 2, where the surface mount mechanism is further configured to move the at least one semiconductor device to a respective predetermined position, the image collector is further configured to collect an image of the semiconductor device, and the controller is further configured to control, based on the collected image of the semiconductor device, the surface mount mechanism to move the at least one semiconductor device to the respective predetermined position.

Solution 4. The pre-assembly device according to any one of Solutions 1 to 3, where the surface mount mechanism includes a suction head and a robotic arm connected to the suction head.

Solution 5. The pre-assembly device according to any one of Solutions 1 to 4, further including:
an adhesive dispenser, configured to dispense adhesive on the at least one side of the cushion block to bond and fix the at least one semiconductor device to a corresponding side of the cushion block.

Solution 6. The pre-assembly device according to Solution 5, further including a curing machine configured to bake and fix the cushion block and the semiconductor device that are bonded.

Solution 7. The pre-assembly device according to any one of Solutions 1 to 6, where the clamping fixture includes a cushion block fixing apparatus configured to fix the cushion block in the first predetermined area.

Solution 8. The pre-assembly device according to Solution 7, where the second member is provided with a hole in the first predetermined area, and the cushion block fixing apparatus includes a vacuum machine in fluid communication with the hole and configured to adsorb and fix the cushion block in the first predetermined area.

Solution 9. The pre-assembly device according to Solution 8, where the clamping fixture includes a vacuum cavity in fluid communication with the hole and the vacuum machine.

Solution 10. The pre-assembly device according to any one of Solutions 1 to 9, where the surface mount mechanism further includes a film mounting machine configured to mount a protective film on a surface of the semiconductor device.

Solution 11. The pre-assembly device according to any one of Solutions 1 to 10, where the cushion block is made of glass, and the clamping fixture is made of stainless steel.

Solution 12. The pre-assembly device according to any one of Solutions 1 to 11, where the semiconductor device is a silicon photomultiplier (SiPM).

Solution 13. The pre-assembly device according to any one of Solutions 1 to 12, where the semiconductor device includes a first side configured to abut against one side of a first member among the at least one first member, and a second side configured to abut against a side among the at least one side of the cushion block.

Solution 14. The pre-assembly device according to any one of Solutions 1 to 13, where the semiconductor device includes an optoelectronic chip for a laser radar.

Solution 15. A surface mount device, including the pre-assembly device for semiconductor devices according to any one of Solutions 1 to 14.

The above description is merely an explanation of preferred embodiments of the present disclosure and the technical principles applied. Those skilled in the art should understand that the scope of the invention involved in the embodiments of the present disclosure is not limited to technical solutions formed by specific combinations of the above technical features, and should also cover other technical solutions formed by any combination of the above technical features or their equivalent features without departing from the above inventive concept, for example, technical solutions formed by mutually replacing the above features with (but not limited to) technical features with similar functions disclosed in the embodiments of the present disclosure.

1. A pre-assembly device for semiconductor devices, comprising:
a clamping fixture, comprising at least one first member for limiting a position of at least one semiconductor device in at least a first direction, and a second member having a first predetermined area for arranging a cushion block; and
a surface mount mechanism, configured to move the cushion block to the first predetermined area;
wherein at least one side of the cushion block is used to limit the position of the at least one semiconductor device in at least a second direction that differs from the first direction and lies in the same plane as the first direction.

2. The pre-assembly device according to claim 1, further comprising: an image collector, configured to collect images of the cushion block and the first predetermined area; and
a controller, communicatively connected to the image collector and the surface mount mechanism, and configured to determine a position of the cushion block relative to the first predetermined area based on the images of the cushion block and the first predetermined area, and control, based on the position, the surface mount mechanism to move the cushion block to the first predetermined area.

3. The pre-assembly device according to claim 2, wherein the surface mount mechanism is further configured to move the at least one semiconductor device to a respective predetermined position, the image collector is further configured to collect an image of the semiconductor device, and the controller is further configured to control, based on the collected image of the semiconductor device, the surface mount mechanism to move the at least one semiconductor device to the respective predetermined position.

4. The pre-assembly device according to claim 1, wherein the surface mount mechanism comprises a suction head and a robotic arm connected to the suction head.

5. The pre-assembly device according to claim 1, further comprising:
an adhesive dispenser, configured to dispense adhesive on the at least one side of the cushion block to bond and fix the at least one semiconductor device to a corresponding side of the cushion block.

6. The pre-assembly device according to claim 5, further comprising a curing machine configured to bake and fix the cushion block and the semiconductor device that are bonded.

7. The pre-assembly device according to claim 1, wherein the clamping fixture comprises a cushion block fixing apparatus configured to fix the cushion block in the first predetermined area.

8. The pre-assembly device according to claim 7, wherein the second member is provided with a hole in the first predetermined area, and the cushion block fixing apparatus comprises a vacuum machine in fluid communication with the hole and configured to adsorb and fix the cushion block in the first predetermined area.

9. The pre-assembly device according to claim 8, wherein the clamping fixture comprises a vacuum cavity in fluid communication with the hole and the vacuum machine.

10. The pre-assembly device according to claim 1, wherein the surface mount mechanism further comprises a film mounting machine configured to mount a protective film on a surface of the semiconductor device.

11. The pre-assembly device according to claim 1, wherein the cushion block is made of glass, and the clamping fixture is made of stainless steel.

12. The pre-assembly device according to claim 1, wherein the semiconductor device is a silicon photomultiplier (SiPM).

13. The pre-assembly device according to claim 1, wherein the semiconductor device comprises a first side configured to abut against one side of a first member among the at least one first member, and a second side configured to abut against a side among the at least one side of the cushion block.

14. The pre-assembly device according to claim 1, wherein the semiconductor device comprises an optoelectronic chip for a laser radar.

15. A surface mount device, comprising the pre-assembly device for semiconductor devices according to claim 1.
